(19) United States
(12) Patent Application Publication
(10) Pub. No.: US 2012/0032054 A1
(43) Pub. Date: Feb. 9, 2012

(54) STACKABLE HOLDER FOR AN INTEGRATED CIRCUIT PACKAGE

(76) Inventor: Tzung-Lin Huang, Kaohsiung City (TW)

(21) Appl. No.: 12/852,723

(22) Filed: Aug. 9, 2010

(51) Int. Cl. H05K 7/00

(52) U.S. Cl. 248/346.5

(57) ABSTRACT

A stackable holder for an IC package includes a base portion, a set of confining members that project from an upper surface of the base portion, and a set of abutting members that project from a lower surface of the base portion. The confining members have first ramp surfaces and cooperate to define a receiving space for confining the IC package. The abutting members have second ramp surfaces and are disposed to correspond in position to the confining members such that a projection of each second ramp surface onto a plane of the base portion overlaps a projection of a corresponding first ramp surface onto the plane of the base portion.

### BACKGROUND OF THE INVENTION

1. Field of the Invention

The invention relates to a holder for an integrated circuit package, more particularly to a stackable holder for an integrated circuit package.

2. Description of the Related Art

Referring to FIGS. 1 and 2, a conventional holder for an integrated circuit (IC) package 100 includes a base portion 11, a plurality of first stop walls 12 disposed on an upper surface 111 of the base portion 11, and a plurality of second stop walls 13 disposed on a lower surface 112 of the base portion 11 at staggered positions relative to the first stop walls 12. The upper surface 111 is formed with a recess 14. The first stop walls 12 define a confining space 15 for confining the IC package 100. The IC package 100, such as a ball grid array (BGA) package, includes a package body 101 and an external connection unit 32 on a bottom side of the package body 101.

Referring to FIGS. 2 and 3, when the IC package 100 is disposed in the confining space 15, the external connection unit 102 of the IC package 100 extends into the recess 14 so as to avoid damaging the external connection unit 102 due to contact with the upper surface 111. Holders may be stacked with one of top of the other in a manner that the IC package 100 is limited in the confining space 15 by the first stop walls 12 of the lower holder and the second stop walls 13 of the upper holder. In order to facilitate stacking of the holders, each first stop wall 12 on the lower holder should be spaced apart by a distance (D) from a corresponding pair of the second stop walls 13 on the upper holder.

However, due to vibrations or forces experienced during transport, the first and second stop walls 12, 13 on the stacked holders might be moved relative to each other or the package body 101 of the IC package 100 might deviate to the position shown in phantom lines in FIG. 3, thereby resulting in possible damage to the package body 101 or the external connection unit 102 of the IC package 100.

### SUMMARY OF THE INVENTION

Therefore, the object of the present invention is to provide a stackable holder that is convenient to use and that is highly stable.

Accordingly, a stackable holder of this invention includes a base portion, a set of confining members, and a set of abutting members. The base portion has an upper surface, a lower surface, and a surrounding surface that interconnects peripheries of the upper and lower surfaces. The confining members project upwardly from the upper surface of the base portion. Each of the confining members has a top surface that is spaced apart from the upper surface of the base portion, a first ramp surface that extends from the upper surface of the base portion to the top surface, an outer wall surface that extends from the upper surface of the base portion to the top surface and the first ramp surface, and an inner wall surface that extends from the upper surface of the base portion to the top surface and the first ramp surface. The inner and outer wall surfaces are respectively disposed distal from and proximate to the surrounding surface. The inner wall surfaces of the confining members cooperate to define a receiving space for confining an integrated circuit package. The abutting members project downwardly from the lower surface of the base portion. Each of the abutting members has a bottom surface that is spaced apart from the lower surface of the base portion, and a second ramp surface that extends from the bottom surface to the lower surface of the base portion. The abutting members are disposed to correspond in position to the confining members such that a projection of each of the second ramp surfaces onto a plane of the base portion overlaps a projection of a corresponding one of the first ramp surfaces of the confining members onto the plane of the base portion.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of a conventional holder for an IC package;

FIG. 2 is a sectional view of a pair of the conventional holders when stacked with one on top of the other;

FIG. 3 is a schematic top view of the conventional holder and an IC package;

FIG. 4 is a top perspective view of the first preferred embodiment of a stackable holder for an IC package according to the present invention;

FIG. 5 is a bottom perspective view of the first preferred embodiment;

FIG. 6 is a schematic side view of the first preferred embodiment;

FIG. 7 is a perspective view of a pair of the holders of the first preferred embodiment when stacked with one on top of the other;

FIG. 8 is a sectional view of a pair of the holders of the first preferred embodiment when stacked with one on top of the other;

FIG. 9 is a sectional view of the second preferred embodiment of a stackable holder for an IC package according to the present invention;

FIG. 10 is a top perspective view of the third preferred embodiment of a stackable holder for an IC package according to the present invention;

FIG. 11 is a bottom perspective view of the third preferred embodiment;

FIG. 12 is a perspective view of the fourth preferred embodiment of a stackable holder for an IC package according to the present invention;

FIG. 13 is a sectional view of the fifth preferred embodiment of a stackable holder for an IC package according to the present invention; and

FIG. 14 is a sectional view of a pair of stackable holders of the sixth preferred embodiment according to the present invention when stacked with one on top of the other.

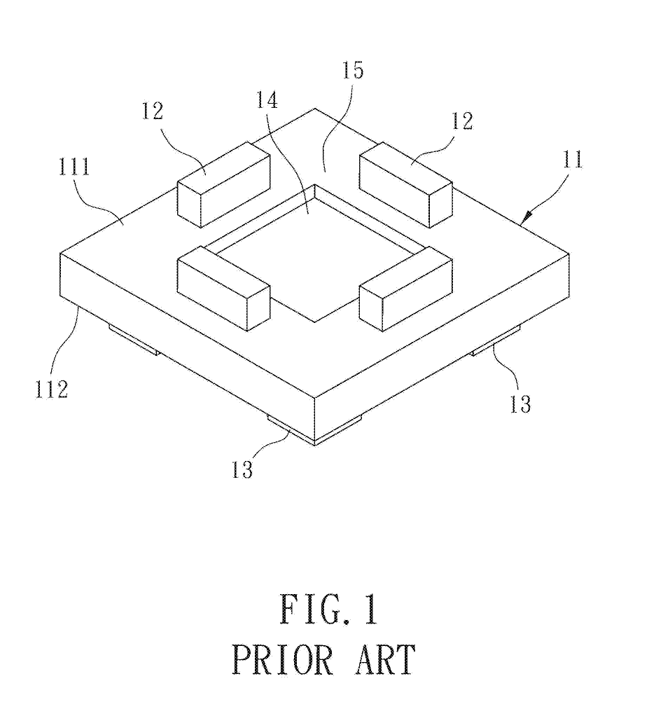

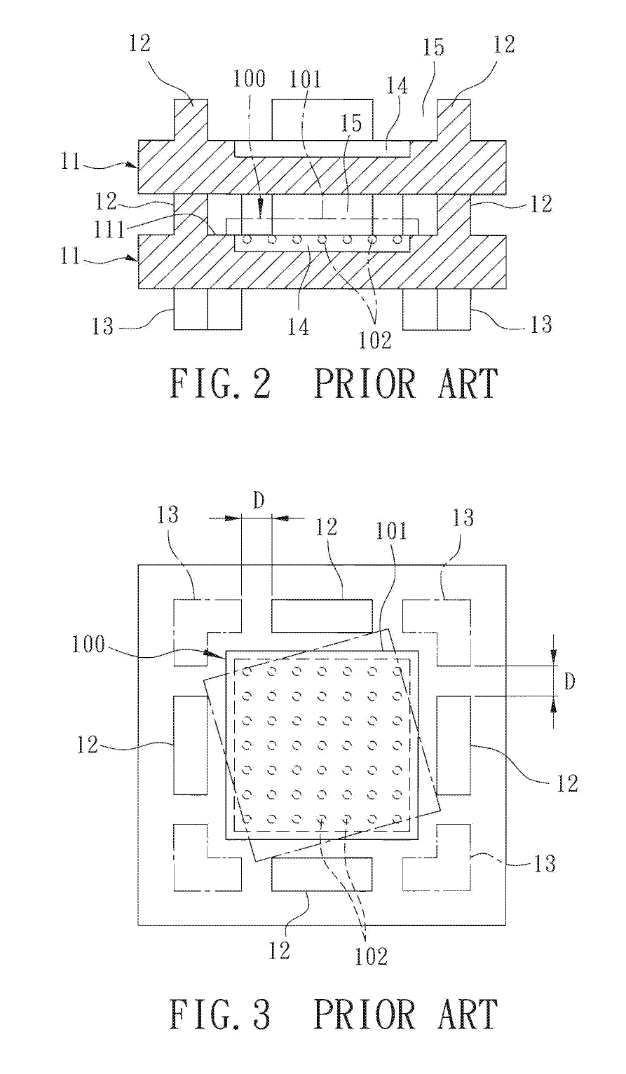

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

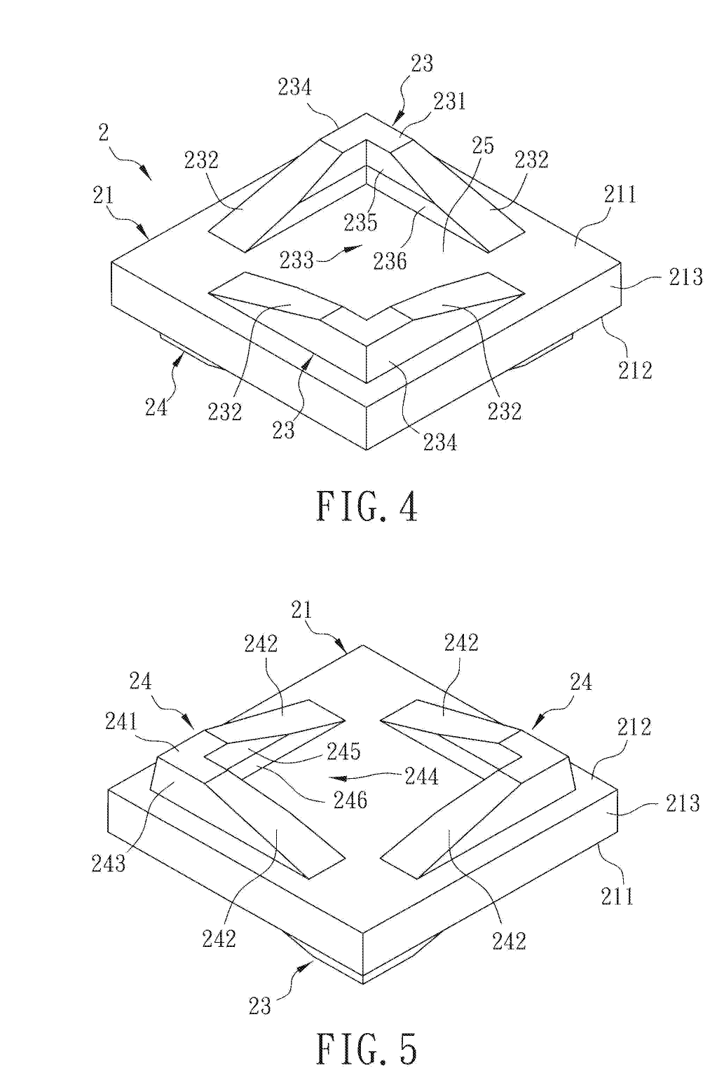

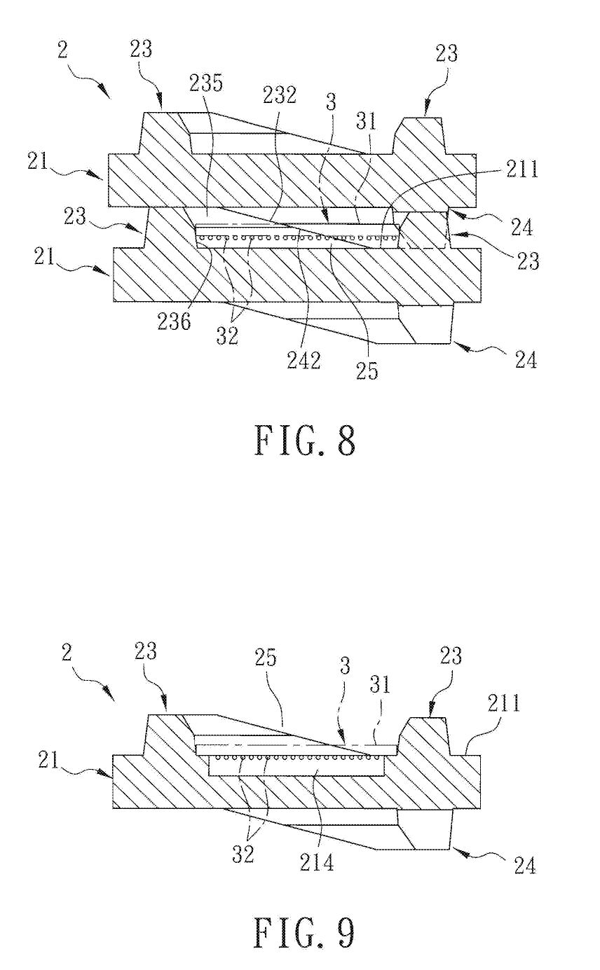

Referring to FIGS. 4 and 5, the first preferred embodiment of a stackable holder 2 according to the present invention is shown to include a base portion 21 having an upper surface 211, a lower surface 212, and a surrounding surface 213 that interconnects peripheries of the upper and lower surfaces. The holder 2 further includes a set of confining members 23 that project upwardly from the upper surface 211 of the base portion 21. In this embodiment, there are two generally L-shaped confining members 23, each having a top surface 231 that is spaced apart from the upper surface 211 of the base portion 21, a pair of first ramp surfaces 232 that extend from the upper surface 211 of the base portion 21 to the top surface 231, an outer wall surface 234 that extends from the upper surface 211 of the base portion 21 to the top surface 231 and the first ramp surfaces 232, and an inner wall surface 233 that extends from the upper surface 211 of the base portion 21 to the top surface 231 and the first ramp surfaces 232. The inner and outer wall surfaces 233, 234 are respectively disposed distal from and proximate to the surrounding surface 213. The inner wall surfaces 233 of the confining members 23 cooperate to define a receiving space 25 for confining an integrated circuit (IC) package 3 (see FIG. 8). The stackable holder 2 further includes a set of abutting members 24 that project downwardly from the lower surface 212 of the base portion 21. In this embodiment, there are two generally L-shaped abutting members 24, each having a bottom surface 241 that is spaced apart from the lower surface 212 of the base portion 21, and a pair of second ramp surfaces 242 that extend from the bottom surface 241 to the lower surface 212 of the base portion 21. The abutting members 24 are disposed to correspond in position to the confining members 23 such that a projection of each of the second ramp surfaces 242 onto a plane of the base portion 21 overlaps a projection of a corresponding one of the first ramp surfaces 232 of the confining members 23 onto the plane of the base portion 21.

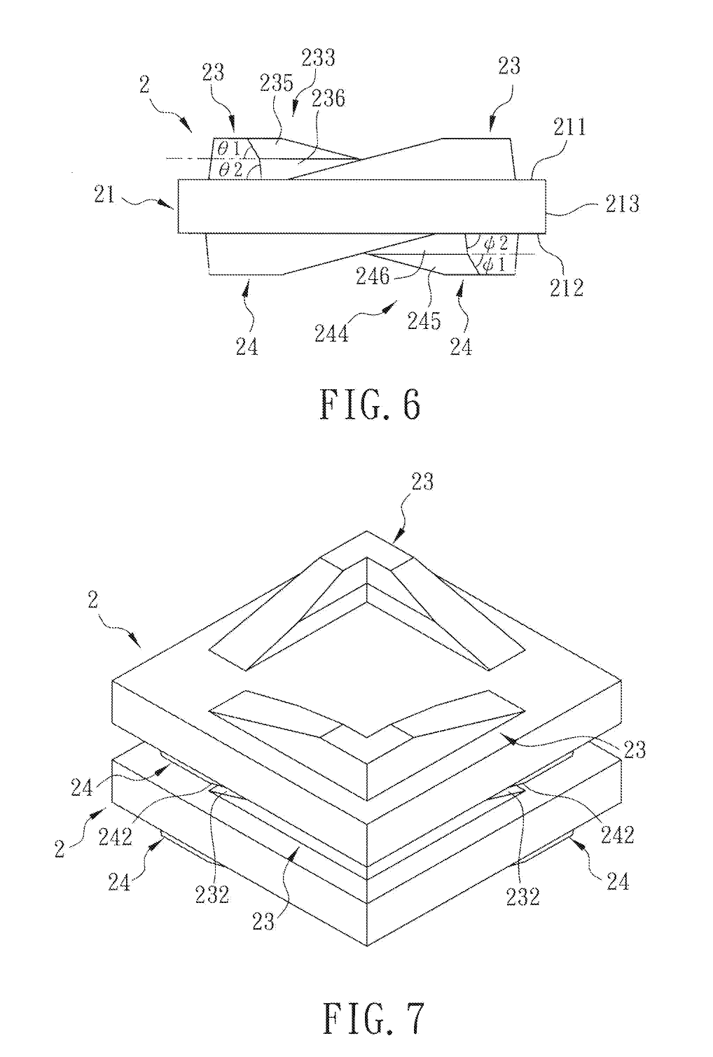

Referring to FIGS. 4 to 7, in this embodiment, the inner wall surface 233 of each of the confining members 23 is shown to have a first inclined surface section 235 that extends from the top surface 231 and the first ramp surfaces 232 and that forms a first angle (θ1) with an imaginary plane parallel to the upper surface 211 of the base portion 21, and a second inclined surface section 236 that extends from the first inclined surface section 235 and the first ramp surfaces 232 to the upper surface 211 of the base portion 21 and that forms a second angle (θ2) with the upper surface 211 of the base portion 21. The second angle (θ2) is different from the first angle (θ1). According to the first embodiment of this invention, the first angle (θ1) is smaller than the second angle (θ2).

Referring to FIGS. 5 to 7, in this embodiment, each of the abutting members 24 further has an outside wall surface 243 that extends from the lower surface 212 of the base portion 21 to the bottom surface 291 and the second ramp surfaces 242, and an inside wall surface 244 that extends from the lower surface 212 of the base portion 21 to the bottom surface 241 and the second ramp surfaces 242. The inside wall surface 299 and the outside wall surface 243 are respectively disposed distal from and proximate to the surrounding surface 213. In this embodiment, the inside wall surface 244 of each of the abutting members 24 has a first inclined surface segment 245 that extends from the bottom surface 212 and the second ramp surfaces 242 and that forms a third angle (φ1) with an imaginary plane parallel to the lower surface 212 of the base portion 21, and a second inclined surface segment 246 that extends from the first inclined surface segment 295 and the second ramp surfaces 242 to the lower surface 212 of the base portion 21 and that forms a fourth angle (φ2) with the lower surface 212 of the base portion 21. The fourth angle (φ2) is different from the third angle (φ1). According to the first embodiment of this invention, the third angle (φ1) is smaller than the fourth angle (φ2), which corresponds to the relationship between the first angle (θ1) and the second angle (θ2) of the first embodiment.

Preferably, inclination of the second ramp surfaces 242 of the abutting members 24 complements inclination of the first ramp surfaces 232 of the confining members 23 to maximize contact area therebetween.

Referring to FIGS. 7 and 8, in use, an IC package 3 is disposed in the receiving space 25 of a lower holder 2. The IC package 3 includes a package body 31 and an external connection unit 32 on a bottom side of the package body 31.

When disposing the IC package 3 in the lower holder 2, the first inclined surface section 235 and the second inclined surface section 236 of each of the confining members 23 help to guide the package body 31 of the IC package 3 so that the package body 31 of the IC package 3 can be confined in the receiving space 25. In this embodiment, the second inclined surface sections 236 of the confining members 23 are configured to enable a bottom peripheral edge of the package body 31 of the IC package 3 to rest thereon. Therefore, by virtue of the second inclined surface sections 236, the external connection unit 32 may be spaced apart from the upper surface 211 of the base portion 21 so as to avoid damaging the external connection unit 32 due to contact with the upper surface 211.

When an upper holder 3 is stacked on top of the lower holder 2, the second ramp surfaces 242 of the abutting members 24 of the upper holder 2 are brought to abut against the first ramp surfaces 232 of the confining members 23 of the lower holder 2. Accordingly, when the upper and lower holders 2 are stacked together, the first and second ramp surfaces 232, 242 cooperate to provide a guiding function such that the two holders 2 may be stacked together with relative ease. Furthermore, when the two holders 2 are stacked together, the extending-type design of the first ramp surfaces 232 and the second ramp surfaces 242 are able to disperse external forces and prevent relative movement therebetween such that the IC package 3 on the lower holder 3 may also be prevented from moving in the receiving space 25. The stackable holder 2 of this invention is thus highly stable and can prevent damage to the IC package 3 confined therein.

In other embodiments of this invention, the inner wall surface 233 of each confining member 23 may be one that is perpendicular to the upper surface 211 of the base portion 21, and the inside wall surface 244 of each abutting member 24 may be one that is perpendicular to the lower surface 212 of the base portion 21. As long as the confining members 23 are provided with the first ramp surfaces 232, and as long as the abutting members 24 are provided with the second ramp surfaces 242, the advantages of dispersing external forces and preventing relative movement between stacked holders 2 may be achieved.

Referring to FIG. 9, the second preferred embodiment of a stackable holder 2 for an IC package 3 according to this invention is shown to be generally similar to the first preferred embodiment in construction. However, in the second preferred embodiment, the upper surface 211 of the base portion is formed with a recess 214 that is in spatial communication with the receiving space 25 and that is adapted for extension of the external connection unit 32 of the IC package 3 to be confined within the receiving space 25. The recess 214 is surrounded by the confining members 23.

In this embodiment, in addition to the effects provided by the first preferred embodiment, when the IC package 3 is disposed in the receiving space 25, the bottom side of the package body 31 abuts against the upper surface 211 of the base portion 21, and the external connection unit 32 extends into the recess 219 so as to avoid possible damage thereto due to contact with the upper surface 211.

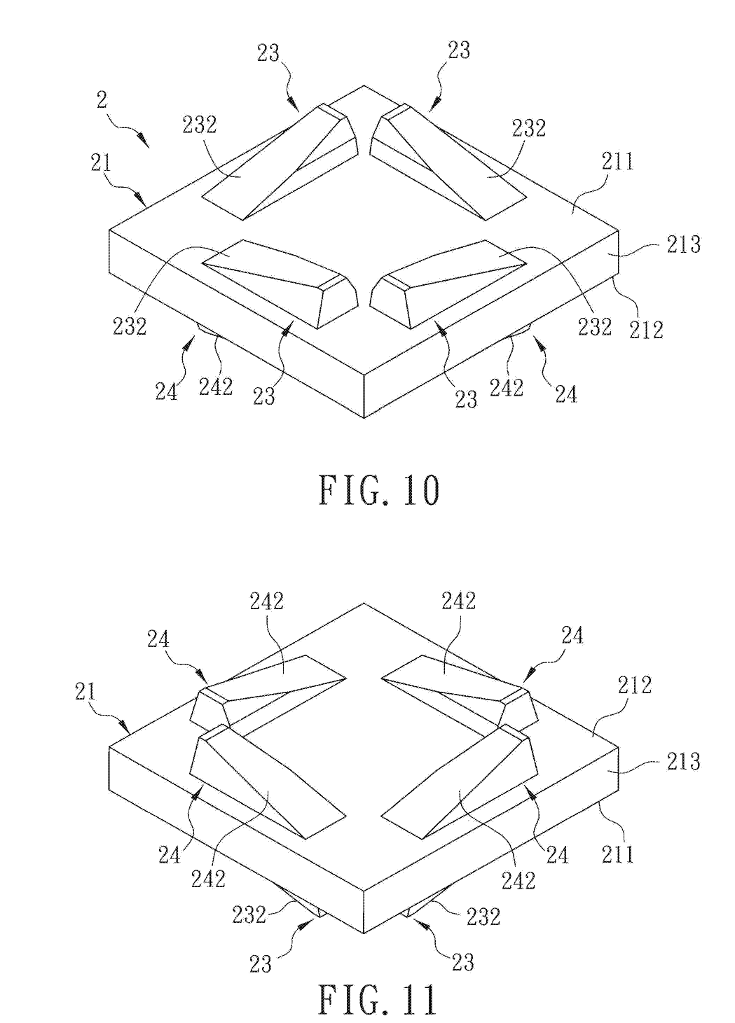

Referring to FIGS. 10 and 11, the third preferred embodiment of a stackable holder 2 for an IC package according to this invention is shown to be generally similar to the first preferred embodiment in construction. The third preferred embodiment differs from the first preferred embodiment in that this embodiment includes four confining members 23 and four abutting members 24, and each of the confining members 23 and each of the abutting members 24 has a wedge shape. In this embodiment, each of the confining members 23 has one first ramp surface 232 and each of the abutting members 29 has one second ramp surface 242.

In this embodiment, in addition to the effects provided by the first preferred embodiment, molding of the stackable holder 2 is made easier because of the simpler configurations of the confining members 23 and the abutting members 29 compared to those in the first preferred embodiment.

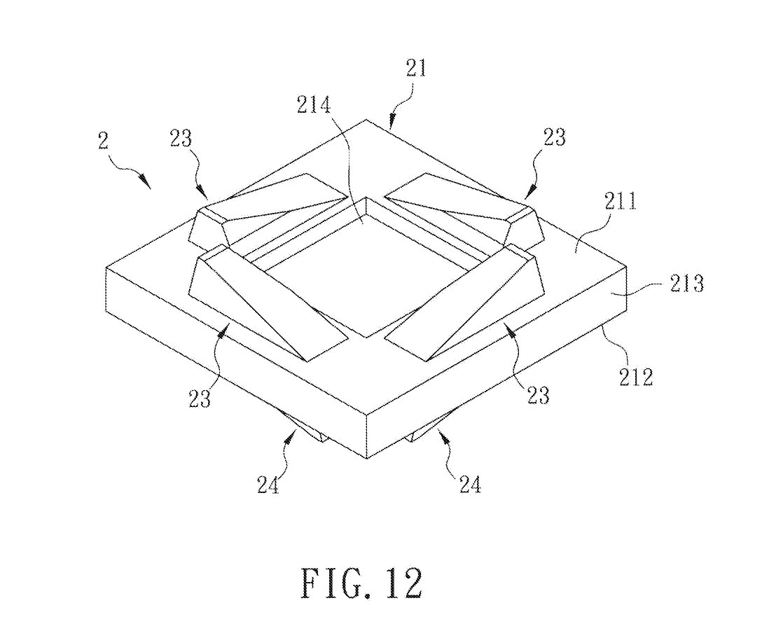

Referring to FIG. 12, the fourth preferred embodiment of a stackable holder 2 for an IC package according to this invention is shown to be generally similar to the third preferred embodiment in construction. The fourth preferred embodiment differs from the third preferred embodiment in that the upper surface 211 of the base portion 21 is formed with a recess 214 that is in spatial communication with the receiving space 25 and that is adapted for extension of the external connection unit 32 of the IC package 3 (see FIG. 8) to be confined within the receiving space 25. The recess 214 is surrounded by the confining members 23.

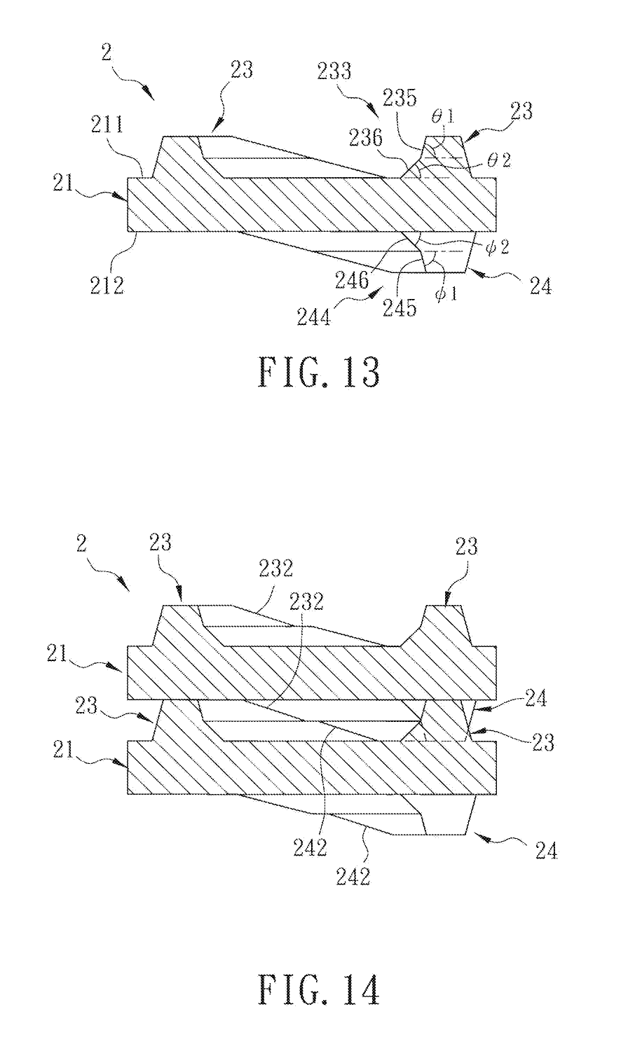

Referring to FIG. 13, the fifth preferred embodiment of a stackable holder 2 for an IC package according to this invention is shown to be generally similar to the first preferred embodiment in construction. The fifth preferred embodiment differs from the first preferred embodiment in that the angle (θ1) formed between the first inclined surface section 235 and the imaginary plane parallel to the upper surface 211 of the base portion 21 is greater than the angle (θ2) formed between the second inclined surface section 236 and the upper surface 211 of the base portion 21. Moreover, the third angle (θ1) formed between the first inclined surface segment 245 and the imaginary plane parallel to the lower surface 212 of the base portion 21 is greater than the fourth angle (θ2) formed between the second inclined surface segment 246 and the lower surface 212 of the base portion 21.

Referring to FIG. 14, the sixth preferred embodiment of a stackable holder 2 for an IC package according to this invention is shown to be similar to the first preferred embodiment in construction. However, in this embodiment, the first ramp surfaces 232 of the confining members 23 and the second ramp surfaces 242 of the abutting members 24 are complementary stepped ramp surfaces. The stepped configuration of the first and second ramp surfaces 232, 242 results in greater friction therebetween to enhance prevention against relative movement between stacked holders 2.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A stackable holder for an integrated circuit package, comprising:
a base portion having an upper surface, a lower surface, and a surrounding surface that interconnects peripheries of said upper and lower surfaces;
a set of confining members that project upwardly from said upper surface of said base portion, each of said confining members having
a top surface that is spaced apart from said upper surface of said base portion,
a first ramp surface that extends from said upper surface of said base portion to said top surface,
an outer wall surface that extends from said upper surface of said base portion to said top surface and said first ramp surface, and
an inner wall surface that extends from said upper surface of said base portion to said top surface and said first ramp surface,
said inner and outer wall surfaces being respectively disposed distal from and proximate to said surrounding surface,
said inner wall surfaces of said confining members cooperating to define a receiving space for confining the integrated circuit package; and
a set of abutting members that project downwardly from said lower surface of said base portion, each of said abutting members having
a bottom surface that is spaced apart from said lower surface of said base portion, and
a second ramp surface that extends from said bottom surface to said lower surface of said base portion;
wherein said abutting members are disposed to correspond in position to said confining members such that a projection of each of said second ramp surfaces onto a plane of said base portion overlaps a projection of a corresponding one of said first ramp surfaces of said confining members onto the plane of said base portion.

2. The stackable holder as claimed in claim 1, wherein said second ramp surfaces of said abutting members complement said first ramp surfaces of said confining members.

3. The stackable holder as claimed in claim 2, wherein each of said first and second ramp surfaces is a stepped ramp surface.

4. The stackable holder as claimed in claim 1, wherein said upper surface of said base portion is formed with a recess that is in spatial communication with said receiving space and that is adapted for extension of an external connection unit of the integrated circuit package to be confined within said receiving space.

5. The stackable holder as claimed in claim 1, wherein said inner wall surface of each of said confining members has a first inclined surface section that extends from said top surface and said first ramp surface and that forms a first angle with an imaginary plane parallel to said upper surface of said base portion, and a second inclined surface section that extends from said first inclined surface section and said first ramp surface to said upper surface of said base portion and that forms a second angle with said upper surface of said base portion, said second angle being different from said first angle.

6. The stackable holder as claimed in claim 5, wherein said first angle is smaller than said second angle.

7. The stackable holder as claimed in claim 5, wherein said first angle is greater than said second angle.

8. The stackable holder as claimed in claim 5, wherein each of said abutting members further has an outside wall surface that extends from said lower surface of said base portion to said bottom surface and said second ramp surface, and an inside wall surface that extends from said lower surface of said base portion to said bottom surface and said second ramp surface, said inside and outside wall surfaces being respectively disposed distal from and proximate to said surrounding surface,
said inside wall surface of each of said abutting members having a first inclined surface segment that extends from said bottom surface and said second ramp surface and that forms a third angle with an imaginary plane parallel to said lower surface of said base portion, and a second inclined surface segment that extends from said first inclined surface segment and said second ramp surface to said lower surface of said base portion and that forms a fourth angle with said lower surface of said base portion, said fourth angle being different from said third angle.

9. The stackable holder as claimed in claim 8, wherein said first angle is smaller than said second angle, and said third angle is smaller than said fourth angle.

10. The stackable holder as claimed in claim 8, wherein said first angle is greater than said second angle, and said third angle is greater that said fourth angle.
